(19) United States
(12) Patent Application Publication
(10) Pub. No.: US 2024/0232469 A9
(43) Pub. Date: Jul. 11, 2024

(54) SYSTEM, SERVER, AND METHOD FOR PREDICTING AND CONTROLLING EMISSIONS IN AN INDUSTRIAL ENVIRONMENT

(71) Applicant: AVEVA SOFTWARE, LLC, Lake Forest, CA (US)

(72) Inventor: Kartik Vanapalli, Hyderabad (IN)

(21) Appl. No.: 18/492,552

(22) Filed: Oct. 23, 2023

Related U.S. Application Data
(60) Provisional application No. 63/418,238, filed on Oct. 21, 2022.

(51) Int. Cl. G06F 30/20

(52) U.S. Cl. CPC G06F 30/20

(57) ABSTRACT

In some embodiments, the disclosure is directed to a system configured to enable a user to link a simulated component to historical and/or near real time data from an operational plant. In some embodiments, the system instructs the process model to link the data to a process simulation. In some embodiments, the system is configured to enable a user to link to historical and/or near real time data for an emissions capturing component from an operational plant to a simulated component to obtain more accurate simulated emissions capture data. In some embodiments, the system is configured to automatically add emissions capturing components to the simulation environment to reduce emissions. In some embodiments, the system is configured to modify inputs and/or outputs for real components to achieve a lower or lowest emission configuration.

### CROSS-REFERENCE TO RELATED APPLICATION

This application claims priority and benefit of U.S. Provisional Application No. 63/418,238, filed Oct. 21, 2022, the contents of which are incorporated herein by reference in its entirety.

### BACKGROUND

Emissions of greenhouse gases adversely impact climate change. As technology improves, there are more devices and techniques available to minimize greenhouse gas emissions from manufacturing and other industrial facilities. However, there are no modeling systems that are able to model emission outputs from components at the design phase. In addition, systems that can capture emissions are not available as models that can be easily integrated into process model simulations, and therefore their effectiveness cannot be assessed before construction begins on the actual process. In addition, there are significant differences in emission regulations in various regions of the world, as well as the availability of compatible components, so available systems that can reduce emissions are often not readily apparent when designing different types of plant simulation models.

Therefore, there is a need in the art for a system that can identify sources of greenhouse gases in the design phase as well as provide a library of easily integrated emission mitigating structures for testing.

### SUMMARY

In some embodiments, the disclosure is directed to a system for calculating emissions at runtime. In some embodiments, the system comprises one or more computers comprising one or more processors and one or more non-transitory computer readable media, the one or more non-transitory computer readable media including program instructions thereon that when executed cause the one or more computers to execute one or more steps. Some embodiments includes a step to generate, by the one or more processors, a simulation environment. Some embodiments includes a step to generate, by the one or more processors, one or more simulated components representing one or more real components for use in a real-world industrial environment. Some embodiments includes a step to receive, by the one or more processors, one or more historical emission values for the one or more real components from one or more historical databases. Some embodiments includes a step to generate, by the one or more processors, one or more emissions simulation models that fit a behavior of the one or more real components based on the one or more historical emission values.

In some embodiments, the one or more non-transitory computer readable media further include program instructions thereon that when executed cause the one or more computers to receive, by the one or more processors, one or more current emission values from the one or more historical databases for each of the one or more real components. Some embodiments includes a step to link, by the one or more processors, the one or more current emission values to the one or more simulated components.

In some embodiments, the one or more current emission values include near real-time measurements obtained from emission sensors coupled to one or more operating components that are similar to the one or more real components. In some embodiments, the one or more non-transitory computer readable media further include program instructions thereon that when executed cause the one or more computers to execute, by the one or more processors, one or more emission simulations using the one or more current emission values.

In some embodiments, the one or more real components are operating in a real-world process having a first process arrangement. In some embodiments, the one or more simulated components are executing in a simulated process with a second process arrangement. In some embodiments, the second process arrangement is different than the first process arrangement.

In some embodiments, the simulation environment is configured to execute a combination of calculated emission values and the one or more current emission values during execution. In some embodiments, the simulation environment is configured to execute a combination of historical emission values and current emission values during execution. In some embodiments, the simulation environment is configured to execute a combination of calculated emission values, historical emission values, and/or current emission values during execution.

In some embodiments, the one or more non-transitory computer readable media further include program instructions thereon that when executed cause the one or more computers to: receive, by the one or more processors, one or more real component configurations and/or one or more real component inputs that correlate to a time the one or more current emission values were obtained. Some embodiments includes a step to compare, by the one or more processors, the one or more real component configurations and/or the one or more real component inputs to one or more simulated component configurations and/or one or more simulated component inputs. Some embodiments includes a step to determine if the one or more real component configurations and/or one or more real component inputs do not match the one or more simulated component configurations and/or the one or more simulated component inputs. Some embodiments includes a step to generate, by the one or more processors, a new simulation model for the one or more simulated components that fit emission values resulting from the one or more real component configurations and/or the one or more real component inputs.

In some embodiments, the one or more non-transitory computer readable media further include program instructions thereon that when executed cause the one or more computers to receive, by the one or more processors, one or more historical component configurations and/or one or more historical component inputs that correlate to a time the historical emission values were obtained. Some embodiments includes a step to compare, by the one or more processors, the one or more historical component configurations and/or the one or more historical component inputs to one or more simulated component configurations and/or the one or more simulated component inputs. Some embodiments includes a step to determine if the one or more historical component configurations and/or the one or more historical component inputs do not match the one or more simulated components configurations and/or one or more simulated component inputs. Some embodiments includes a step to generate, by the one or more processors, a new simulation model for the one or more simulated components that fit emission values resulting from the one or more historical component configurations and/or the one or more historical component inputs.

In some embodiments, the one or more real components are operating in a real-world process having a first process arrangement of the one or more real components. In some embodiments, the one or more simulated components are executing in a simulated process that includes a digital twin of the first process arrangement. In some embodiments, the digital twin is configured to execute a process change independently of the real process. In some embodiments, the digital twin is configured to calculate emission values for the one or more real components as a result of the process change. In some embodiments, the digital twin is configured to suggest a process configuration based on a production of a lowest emission value.

In some embodiments, the simulation environment incudes an emissions capture library comprising one or more emission capturing components and/or one or more emission capturing configurations. In some embodiments, the simulation environment is configured to automatically suggest one or more emission capturing components and/or emission capturing configurations that reduce the emissions of a simulated component. In some embodiments, the simulation environment is configured to automatically add the one or more emission capturing components to an exhaust of the one or more simulated components.

In some embodiments, the simulation environment incudes an emissions capture library comprising one or more emission capturing process configurations. In some embodiments, the emission capturing configurations include connections between real components emitting emissions and real components configured to at least partially consume the emissions. In some embodiments, the simulation environment is configured to automatically suggest one or more emission capturing configurations that reduce the emissions of a simulated component.

In some embodiments, the simulation environment is configured to automatically modify an emissions exhaust of a simulated component to connect to one or more emission capturing components existing within the simulation environment. In some embodiments, the simulation environment is configured to automatically add one or more emission reducing components to the simulation environment that at least partially consume emissions produced by one or more components. In some embodiments, the simulation environment is configured to automatically modify an emissions exhaust of one or more simulated component to connect to an input for the one or more mission reducing components.

In some embodiments, the simulation environment is configured to automatically replace one or more simulated components in the simulation environment with one or more process components that at least partially consume emissions produced by one or more components. In some embodiments, the simulation environment is configured to automatically modify an emissions exhaust of one or more simulated component to connect to an input for the one or more process components. In some embodiments, the one or more non-transitory computer readable media further include program instructions thereon that when executed cause the one or more computers to execute, by the one or more processors, a process configuration change in a real-world process that directs the emissions to one or more emission consuming components that currently exist in the real process.

### DRAWINGS DESCRIPTION

FIG. 1 illustrates a non-limiting example system workflow according to some embodiments.

FIG. 2 shows a blank canvas for AVEVA Group's E3D Design software that incorporates elements of the system according to some embodiments.

FIG. 3 shows an emissions dashboard provided by the system according to some embodiments.

FIG. 4 illustrates a computer system enabling or comprising the systems and methods in accordance with some embodiments of the system.

### DETAILED DESCRIPTION

In some embodiments, the system is configured to predict industrial facility emissions by using simulation models. In some embodiments, the system is configured to determine how to best lower emissions by tracking different greenhouse gases (e.g., CO₂) produced by an operational component and providing that information into a simulated component model. In some embodiments, the system enables a user to have an overall evaluation of emissions at design time and attain required environmental permissions without significant challenge from government authorities and often time-consuming and expensive rework. In some embodiments, the system helps organizations and governments transition to a lower or low carbon economy.

In some embodiments, the system is configured to collect emission values of greenhouse gases from different components and feed the emission values to a design model. In some embodiments, the system is configured to display a view of emissions at the site/zone level for each individual sub-element and/or total emissions of a site or zone. In some embodiments, the system is configured to collect equipment emission information from one or more databases comprising actual historical emission values from running equipment. In some embodiments, the system is configured to incorporate the actual historical emission values into a simulation model to obtain more accurate emission estimations at the time of design.

In some embodiments, the system includes a dashboard view of emission data within a simulation development environment. In some embodiments, the system is configured to receive actual historical emission data from existing plants and incorporate the historical emission data into the model analysis at any desired time. In some embodiments, the model analysis includes both historical emission values and calculated emission values. In some embodiments, the model analysis includes both historical operational values and near real time operational values. In some embodiments, calculated values include one or more estimated component operational parameters obtained from an equation. In some embodiments, historical values include more component operational parameters obtained from one or more process monitoring devices (e.g., sensors, cameras, etc.). In some embodiments, the system is configured to incorporate both historical and calculated values when executing a simulation model.

In some embodiments, the system is configured to correlate deviation of calculated values from historical values to one or more process configurations and/or process inputs (e.g., raw/refined material). In some embodiments, the system is configured to create, modify, augment, and/or associate specific process models for each process configuration and/or process input identified. In some embodiments, the system is configured to generate a message (e.g., alert, notification, or the like) if a measured emission valued deviates from one or more specified process models. For example, if the system receives an emission value from a reactor vent that deviates from what is expected from a first specific process model, but matches an expected value from a second specific process model, the system is configured to not only generate an alert but also generate a report comprising the process configurations and/or process inputs that match the second process model as possible root cause.

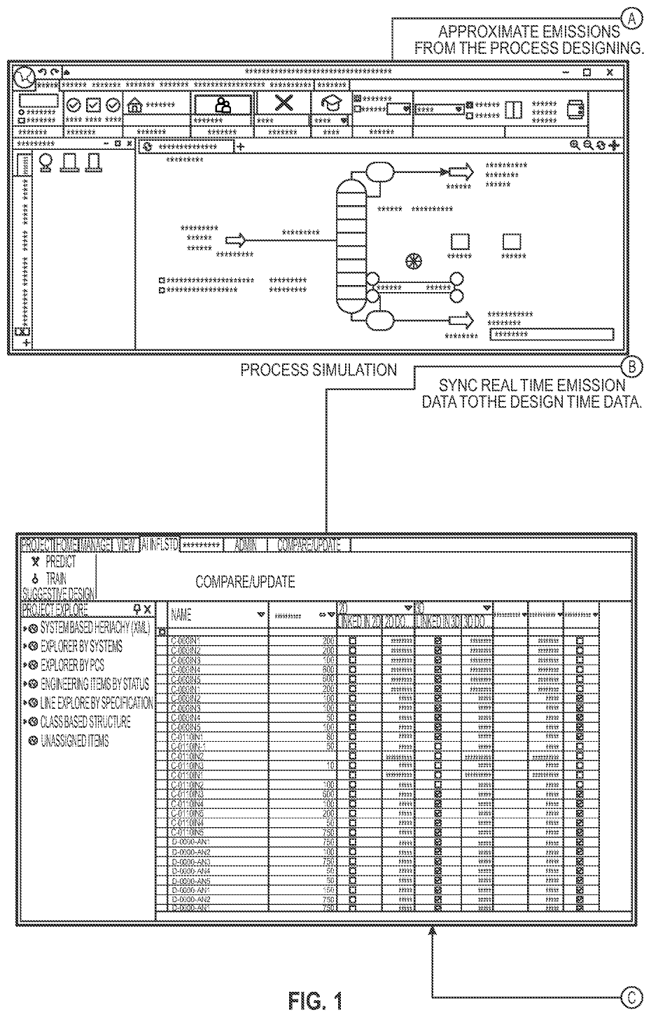

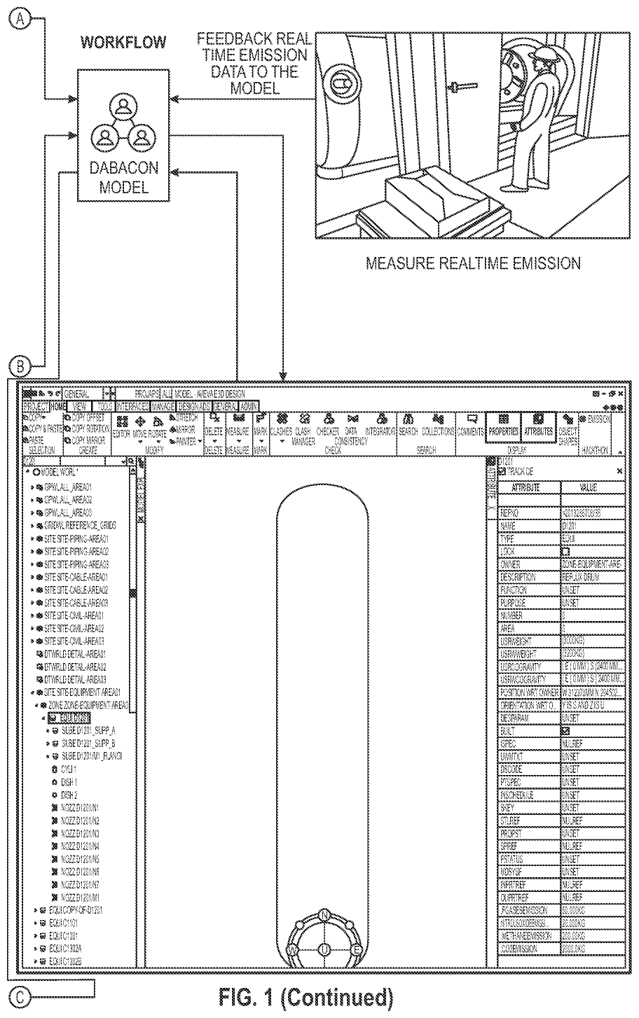

FIG. 1 illustrates a non-limiting example method for creating the emissions prediction system described herein according to some embodiments. Some embodiments include a step of creating a process simulation model using process simulation software. Some embodiments include a step of configuring the simulation model to yield approximate emissions based on calculations using equations that represent each relevant process and/or component (i.e., that impact emissions). Some embodiments include a step of measuring and storing actual equipment parameters and/or emissions as historical values from operational components in one or more operational plants. Some embodiments include a step of incorporating one or more of the historical values into the model.

Some embodiments include a step of creating a link between a modeled component and an operational component generating near real time data. Some embodiments include a step of configuring the modeled component to receive the near real time data via a network connected to one or more components. Some embodiments include a step of using the near real time values in a modeled component instead of using estimates from equations. Some embodiments include a step of comparing the near real time data to the calculated value. Some embodiments include a step of collecting process configurations and/or process inputs of the one or more components. Some embodiments include a step of associating the process configurations and/or process inputs to one or more deviations from the calculated value. Some embodiments include a step of generating one or more specific models that fit each process configuration and/or process input. Some embodiments include a step of generating a digital twin of the simulation configured to execute the one or more specific models independently of the simulation. Some embodiments include a step of instructing the digital twin to determine a process configuration and/or process inputs that result in a lowest value for at least one type of emission. Some embodiments include a step of the system executing a process configuration change and/or or process input change to configured one or more components to the determined process configuration and/or process inputs. In some embodiments, the process execution is automatic.

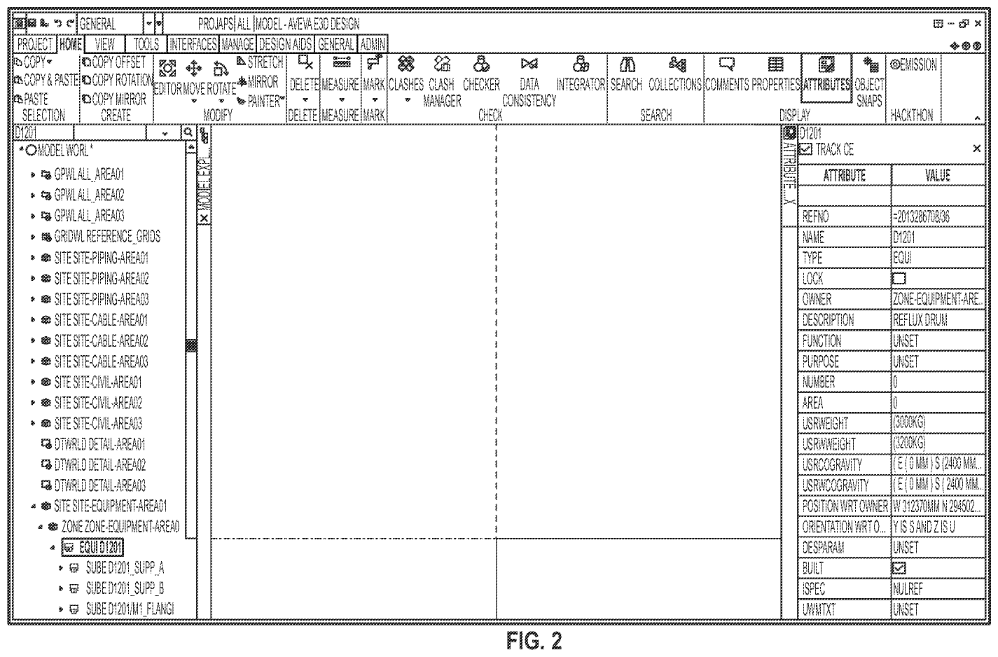

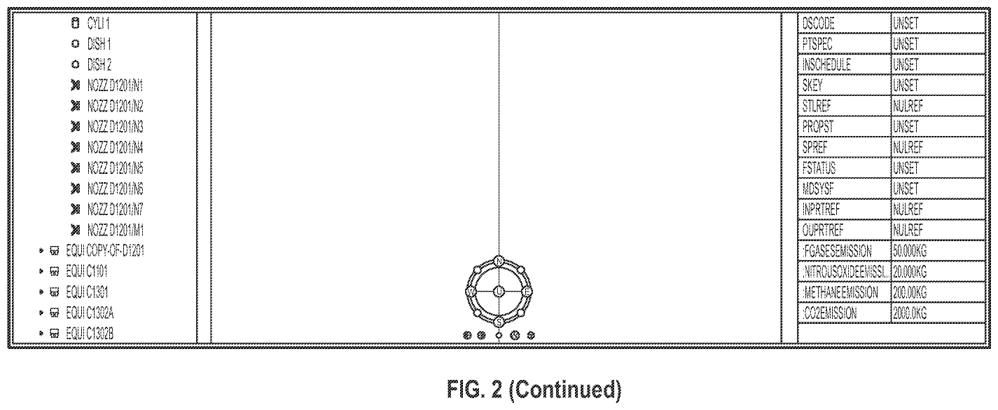

FIG. 2 shows a blank canvas for AVEVA Group's E3D Design software that incorporates elements of the system according to some embodiments. In some embodiments, the left pane enables a user to select equipment from different sites and zones within the process model. In some embodiments, the right pane shows aspects of the system integrated into E3D to capture emission data for one or more of individual equipment components, areas comprising multiple individual components, and zones comprising multiple areas. In this example, only 4 major emissions are shown at the bottom of the list, but any number of emissions of interest can be added according to some embodiments. In some embodiments, the system is configured to associate the emissions with the equipment to provide emission values which are then considered in the process model when the simulation is executed.

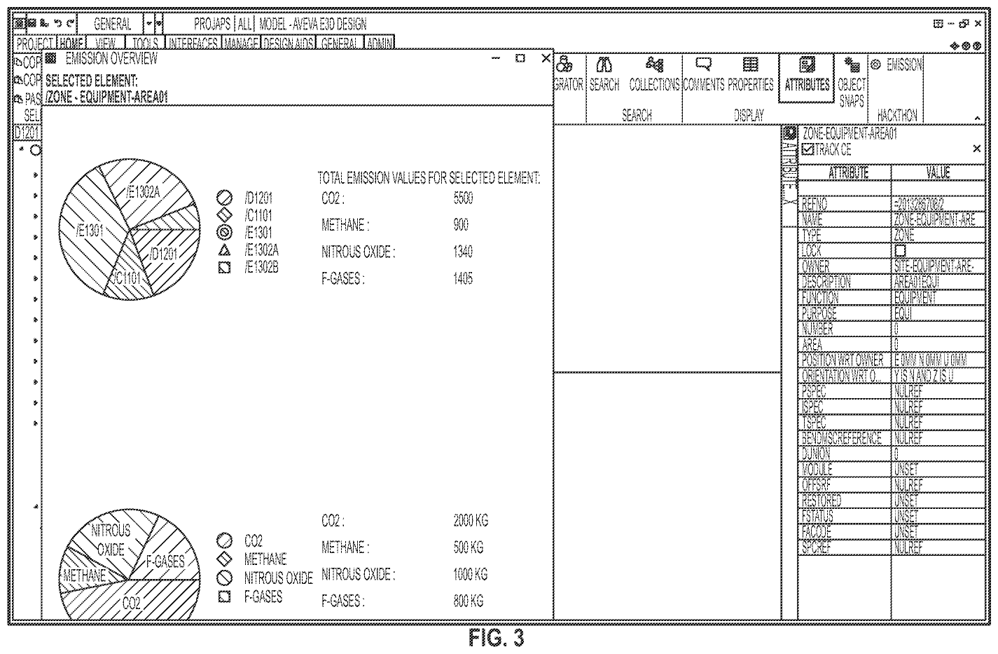

FIG. 3 shows an emissions dashboard provided by the system according to some embodiments. In some embodiments, the dashboard displays the total emissions for a particular zone and/or area. In some embodiments, the system is configured to display a percentage contribution of each type of gas to the total emissions. In some embodiments, the system is configured to display a percentage of each type of gas emissions for one or more equipment components.

In some embodiments, the system enables a user to iterate and improve the model by first providing estimates for emissions based on calculated chemical reactions, and then improve the model by importing historical and/or near real time emission values from operational equipment. As a non-limiting example, a plant designer first uses the system to assign calculated emission values to a simulation model. In some embodiments, the emissions are represented as an output node from a particular components, which can be combined with other components in areas, and nodes from areas can be combined with other zones in a similar fashion such that all or a portion of the total emissions can be identified through the dashboard.

In some embodiments, the system is configured to enable importing one or more emission capturing equipment models from one or more model libraries. In some embodiments, the system is configured to enable a user to connect an emission node from a component, area, and/or zone to the emission capturing equipment model. In some embodiments, once connected, the system is configured to recalculate emissions at an emission node of the emission capturing equipment model which results in a process model that takes into consideration emissions capture.

In some embodiments, the system is configured to enable a user to link a component to historical and/or near real time data in an operational plant and instruct the process model to use those data in the simulation. Similarly, in some embodiments, the system is configured to enable a user to link to historical and/or near real time data for an emissions capturing component in an operational plant to obtain more accurate emissions capture data. In some embodiments, once the links are complete, the simulation can be rerun and new emissions and/or capture data observed. In some embodiments, the results may show that a particular emissions capture component is not sufficient to reduce emissions to an acceptable level. In some embodiments, the system is configured to enable a user to delete the emissions capturing component from the process model and add a different emissions capturing structure to the emissions node from the model library. In some embodiments, This process can be repeated until emissions are reduced to desirable levels according to some embodiments.

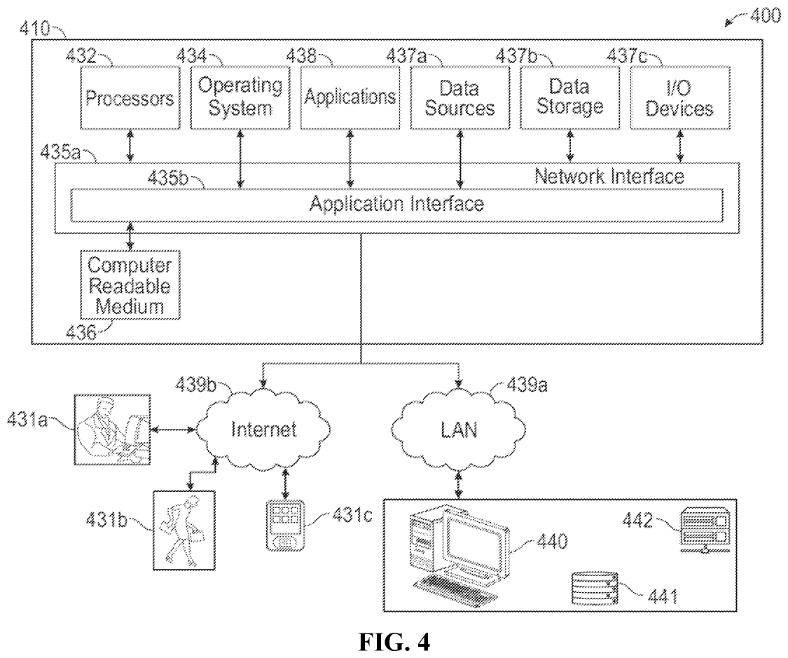

FIG. 4 illustrates a computer system 410 enabling or comprising the systems and methods in accordance with some embodiments of the system. In some embodiments, the computer system 410 can operate and/or process computer-executable code of one or more software modules of the aforementioned system and method. Further, in some embodiments, the computer system 410 can operate and/or display information within one or more graphical user interfaces (e.g., HMIs) integrated with or coupled to the system.

In some embodiments, the computer system 410 can comprise at least one processor 432. In some embodiments, the at least one processor 432 can reside in, or coupled to, one or more conventional server platforms (not shown). In some embodiments, the computer system 410 can include a network interface 435a and an application interface 435b coupled to the least one processor 432 capable of processing at least one operating system 434. Further, in some embodiments, the interfaces 435a, 435b coupled to at least one processor 432 can be configured to process one or more of the software modules (e.g., such as enterprise applications 438). In some embodiments, the software application modules 438 can include server-based software and can operate to host at least one user account and/or at least one client account, and operate to transfer data between one or more of these accounts using the at least one processor 432.

With the above embodiments in mind, it is understood that the system can employ various computer-implemented operations involving data stored in computer systems. Moreover, the above-described databases and models described throughout this disclosure can store analytical models and other data on computer-readable storage media within the computer system 410 and on computer-readable storage media coupled to the computer system 410 according to various embodiments. In addition, in some embodiments, the above-described applications of the system can be stored on computer-readable storage media within the computer system 410 and on computer-readable storage media coupled to the computer system 410. In some embodiments, these operations are those requiring physical manipulation of physical quantities. Usually, though not necessarily, in some embodiments these quantities take the form of one or more of electrical, electromagnetic, magnetic, optical, or magneto-optical signals capable of being stored, transferred, combined, compared and otherwise manipulated. In some embodiments, the computer system 410 can comprise at least one computer readable medium 436 coupled to at least one of at least one data source 437a, at least one data storage 437b, and/or at least one input/output 437c. In some embodiments, the computer system 410 can be embodied as computer readable code on a computer readable medium 436. In some embodiments, the computer readable medium 436 can be any data storage that can store data, which can thereafter be read by a computer (such as computer 440). In some embodiments, the computer readable medium 436 can be any physical or material medium that can be used to tangibly store the desired information or data or instructions and which can be accessed by a computer 440 or processor 432. In some embodiments, the computer readable medium 436 can include hard drives, network attached storage (NAS), read-only memory, random-access memory, FLASH based memory, CD-ROMs, CD-Rs, CD-RWs, DVDs, magnetic tapes, other optical and non-optical data storage. In some embodiments, various other forms of computer-readable media 436 can transmit or carry instructions to a remote computer 440 and/or at least one user 431, including a router, private or public network, or other transmission or channel, both wired and wireless. In some embodiments, the software application modules 438 can be configured to send and receive data from a database (e.g., from a computer readable medium 436 including data sources 437a and data storage 437b that can comprise a database), and data can be received by the software application modules 438 from at least one other source. In some embodiments, at least one of the software application modules 438 can be configured within the computer system 410 to output data to at least one user 431 via at least one graphical user interface rendered on at least one digital display.

In some embodiments, the computer readable medium 436 can be distributed over a conventional computer network via the network interface 435a where the system embodied by the computer readable code can be stored and executed in a distributed fashion. For example, in some embodiments, one or more components of the computer system 410 can be coupled to send and/or receive data through a local area network (“LAN”) 439a and/or an internet coupled network 439b (e.g., such as a wireless internet). In some embodiments, the networks 439a, 439b can include wide area networks (“WAN”), direct connections (e.g., through a universal serial bus port), or other forms of computer-readable media 436, or any combination thereof.

In some embodiments, components of the networks 439a, 439b can include any number of personal computers 440 which include for example desktop computers, and/or laptop computers, or any fixed, generally non-mobile internet appliances coupled through the LAN 439a. For example, some embodiments include one or more of personal computers 440, databases 441, and/or servers 442 coupled through the LAN 439a that can be configured for any type of user including an administrator. Some embodiments can include one or more personal computers 440 coupled through network 439b. In some embodiments, one or more components of the computer system 410 can be coupled to send or receive data through an internet network (e.g., such as network 439b). For example, some embodiments include at least one user 431a, 431b, is coupled wirelessly and accessing one or more software modules of the system including at least one enterprise application 438 via an input and output (“I/O”) 437c. In some embodiments, the computer system 410 can enable at least one user 431a, 431b, to be coupled to access enterprise applications 438 via an I/O 437c through LAN 439a. In some embodiments, the user 431 can comprise a user 431a coupled to the computer system 410 using a desktop computer, and/or laptop computers, or any fixed, generally non-mobile internet appliances coupled through the internet 439b. In some embodiments, the user can comprise a mobile user 431b coupled to the computer system 410. In some embodiments, the user 431b can connect using any mobile computing 431c to wireless coupled to the computer system 410, including, but not limited to, one or more personal digital assistants, at least one cellular phone, at least one mobile phone, at least one smart phone, at least one pager, at least one digital tablets, and/or at least one fixed or mobile internet appliances.

The disclosure describes the specifics of how a machine including one or more computers comprising one or more processors and one or more non-transitory computer readable media implement the system and its improvements over the prior art. The instructions executed by the machine cannot be performed in the human mind or derived by a human using a pen and paper but require the machine to convert process input data to useful output data. Moreover, the claims presented herein do not attempt to tie-up a judicial exception with known conventional steps implemented by a general-purpose computer; nor do they attempt to tie-up a judicial exception by simply linking it to a technological field. Indeed, the systems and methods described herein were unknown and/or not present in the public domain at the time of filing, and they provide technologic improvements advantages not known in the prior art. Furthermore, the system includes unconventional steps that confine the claim to a useful application.

It is understood that the system is not limited in its application to the details of construction and the arrangement of components set forth in the previous description or illustrated in the drawings. The system and methods disclosed herein fall within the scope of numerous embodiments. The previous discussion is presented to enable a person skilled in the art to make and use embodiments of the system. Any portion of the structures and/or principles included in some embodiments can be applied to any and/or all embodiments: it is understood that features from some embodiments presented herein are combinable with other features according to some other embodiments. Thus, some embodiments of the system are not intended to be limited to what is illustrated but are to be accorded the widest scope consistent with all principles and features disclosed herein.

Some embodiments of the system are presented with specific values and/or setpoints. These values and setpoints are not intended to be limiting and are merely examples of a higher configuration versus a lower configuration and are intended as an aid for those of ordinary skill to make and use the system.

Furthermore, acting as Applicant's own lexicographer, Applicant imparts the explicit meaning and/or disavow of claim scope to the following terms:

Applicant defines any use of “and/or” such as, for example, “A and/or B,” or “at least one of A and/or B” to mean element A alone, element B alone, or elements A and B together. In addition, a recitation of “at least one of A, B, and C,” a recitation of “at least one of A, B, or C,” or a recitation of “at least one of A, B, or C or any combination thereof” are each defined to mean element A alone, element B alone, element C alone, or any combination of elements A, B and C, such as AB, AC, BC, or ABC, for example.

“Substantially” and “approximately” when used in conjunction with a value encompass a difference of 5% or less of the same unit and/or scale of that being measured.

“Simultaneously” as used herein includes lag and/or latency times associated with a conventional and/or proprietary computer, such as processors and/or networks described herein attempting to process multiple types of data at the same time. “Simultaneously” also includes the time it takes for digital signals to transfer from one physical location to another, be it over a wireless and/or wired network, and/or within processor circuitry.

As used herein, “can” or “may” or derivations there of (e.g., the system display can show X) are used for descriptive purposes only and is understood to be synonymous and/or interchangeable with “configured to” (e.g., the computer is configured to execute instructions X) when defining the metes and bounds of the system.

In addition, the term “configured to” means that the limitations recited in the specification and/or the claims must be arranged in such a way to perform the recited function: “configured to” excludes structures in the art that are “capable of” being modified to perform the recited function but the disclosures associated with the art have no explicit teachings to do so. For example, a recitation of a “container configured to receive a fluid from structure X at an upper portion and deliver fluid from a lower portion to structure Y” is limited to systems where structure X, structure Y, and the container are all disclosed as arranged to perform the recited function. The recitation “configured to” excludes elements that may be “capable of” performing the recited function simply by virtue of their construction but associated disclosures (or lack thereof) provide no teachings to make such a modification to meet the functional limitations between all structures recited. Another example is “a computer system configured to or programmed to execute a series of instructions X, Y, and Z.” In this example, the instructions must be present on a non-transitory computer readable medium such that the computer system is “configured to” and/or “programmed to” execute the recited instructions: “configure to” and/or “programmed to” excludes art teaching computer systems with non-transitory computer readable media merely “capable of” having the recited instructions stored thereon but have no teachings of the instructions X, Y, and Z programmed and stored thereon. The recitation “configured to” can also be interpreted as synonymous with operatively connected when used in conjunction with physical structures.

It is understood that the phraseology and terminology used herein is for description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The previous detailed description is to be read with reference to the figures, in which like elements in different figures have like reference numerals. The figures, which are not necessarily to scale, depict some embodiments and are not intended to limit the scope of embodiments of the system.

Any of the operations described herein that form part of the invention are useful machine operations. The invention also relates to a device or an apparatus for performing these operations. The apparatus can be specially constructed for the required purpose, such as a special purpose computer. When defined as a special purpose computer, the computer can also perform other processing, program execution or routines that are not part of the special purpose, while still being capable of operating for the special purpose. Alternatively, the operations can be processed by a general-purpose computer selectively activated or configured by one or more computer programs stored in the computer memory, cache, or obtained over a network. When data is obtained over a network the data can be processed by other computers on the network, e.g., a cloud of computing resources.

The embodiments of the invention can also be defined as a machine that transforms data from one state to another state. The data can represent an article, that can be represented as an electronic signal and electronically manipulate data. The transformed data can, in some cases, be visually depicted on a display, representing the physical object that results from the transformation of data. The transformed data can be saved to storage generally, or in particular formats that enable the construction or depiction of a physical and tangible object. In some embodiments, the manipulation can be performed by a processor. In such an example, the processor thus transforms the data from one thing to another. Still further, some embodiments include methods can be processed by one or more machines or processors that can be connected over a network. Each machine can transform data from one state or thing to another, and can also process data, save data to storage, transmit data over a network, display the result, or communicate the result to another machine. Computer-readable storage media, as used herein, refers to physical or tangible storage (as opposed to signals) and includes without limitation volatile and non-volatile, removable and non-removable storage media implemented in any method or technology for the tangible storage of information such as computer-readable instructions, data structures, program modules or other data.

Although method operations are presented in a specific order according to some embodiments, the execution of those steps do not necessarily occur in the order listed unless explicitly specified. Also, other housekeeping operations can be performed in between operations, operations can be adjusted so that they occur at slightly different times, and/or operations can be distributed in a system which allows the occurrence of the processing operations at various intervals associated with the processing, as long as the processing of the overlay operations are performed in the desired way and result in the desired system output.

It will be appreciated by those skilled in the art that while the invention has been described above in connection with particular embodiments and examples, the invention is not necessarily so limited, and that numerous other embodiments, examples, uses, modifications and departures from the embodiments, examples and uses are intended to be encompassed by the claims attached hereto. The entire disclosure of each patent and publication cited herein is incorporated by reference, as if each such patent or publication were individually incorporated by reference herein. Various features and advantages of the invention are set forth in the following claims.

We claim:

1. A system for calculating emissions at runtime comprising:
one or more computers comprising one or more processors and one or more non-transitory computer readable media, the one or more non-transitory computer readable media including program instructions thereon that when executed cause the one or more computers to:
generate, by the one or more processors, a simulation environment;
generate, by the one or more processors, one or more simulated components representing one or more real components for use in a real-world industrial environment;
receive, by the one or more processors, one or more historical emission values for the one or more real components from one or more historical databases; and
generate, by the one or more processors, one or more emissions simulation models that fit a behavior of the one or more real components based on the one or more historical emission values.

2. The system of claim 1,
wherein the one or more non-transitory computer readable media further include program instructions thereon that when executed cause the one or more computers to:
receive, by the one or more processors, one or more current emission values from the one or more historical databases for each of the one or more real components; and
link, by the one or more processors, the one or more current emission values to the one or more simulated components.

3. The system of claim 2,
wherein the one or more current emission values include near real-time measurements obtained from emission sensors coupled to one or more operating components that are similar to the one or more real components.

4. The system of claim 3,
wherein the one or more non-transitory computer readable media further include program instructions thereon that when executed cause the one or more computers to:
execute, by the one or more processors, one or more emission simulations using the one or more current emission values.

5. The system of claim 4,
wherein the one or more real components are operating in a real-world process having a first process arrangement;
wherein the one or more simulated components are executing in a simulated process with a second process arrangement; and
wherein the second process arrangement is different than the first process arrangement.

6. The system of claim 4,
wherein the simulation environment is configured to execute a combination of calculated emission values and the one or more current emission values during execution.

7. The system of claim 4,
wherein the simulation environment is configured to execute a combination of historical emission values and current emission values during execution.

8. The system of claim 4,
wherein the simulation environment is configured to execute a combination of calculated emission values, historical emission values, and/or current emission values during execution.

9. The system of claim 6,
wherein the one or more non-transitory computer readable media further include program instructions thereon that when executed cause the one or more computers to:
receive, by the one or more processors, one or more real component configurations and/or one or more real component inputs that correlate to a time the one or more current emission values were obtained;
compare, by the one or more processors, the one or more real component configurations and/or the one or more real component inputs to one or more simulated component configurations and/or one or more simulated component inputs; and
if the one or more real component configurations and/or one or more real component inputs do not match the one or more simulated component configurations and/or the one or more simulated component inputs, then generate, by the one or more processors, a new simulation model for the one or more simulated components that fit emission values resulting from the one or more real component configurations and/or the one or more real component inputs.

10. The system of claim 6,
wherein the one or more non-transitory computer readable media further include program instructions thereon that when executed cause the one or more computers to:
receive, by the one or more processors, one or more historical component configurations and/or one or more historical component inputs that correlate to a time the historical emission values were obtained;
compare, by the one or more processors, the one or more historical component configurations and/or the one or more historical component inputs to one or more simulated component configurations and/or the one or more simulated component inputs; and
if the one or more historical component configurations and/or the one or more historical component inputs do not match the one or more simulated components configurations and/or one or more simulated component inputs, then generate, by the one or more processors, a new simulation model for the one or more simulated components that fit emission values resulting from the one or more historical component configurations and/or the one or more historical component inputs.

11. The system of claim 8,
wherein the one or more real components are operating in a real process having a first process arrangement of the one or more real components; and
wherein the one or more simulated components are executing in a simulated process that includes a digital twin of the first process arrangement.

12. The system of claim 11,
wherein the digital twin is configured to execute a process change independently of the real process; and
wherein the digital twin is configured to calculate emission values for the one or more real components as a result of the process change.

13. The system of claim 12,
wherein the digital twin is configured to suggest a process configuration based on a production of a lowest emission value.

14. The system of claim 1,
wherein the simulation environment incudes an emissions capture library comprising one or more emission capturing components and/or one or more emission capturing configurations; and
wherein the simulation environment is configured to automatically suggest one or more emission capturing components and/or emission capturing configurations that reduce the emissions of a simulated component.

15. The system of claim 14,
wherein the simulation environment is configured to automatically add the one or more emission capturing components to an exhaust of the one or more simulated components.

16. The system of claim 1,
wherein the simulation environment incudes an emissions capture library comprising one or more emission capturing process configurations;
wherein the emission capturing configurations include connections between real components emitting emissions and real components configured to at least partially consume the emissions; and
wherein the simulation environment is configured to automatically suggest one or more emission capturing configurations that reduce the emissions of a simulated component.

17. The system of claim 14,
wherein the simulation environment is configured to automatically modify an emissions exhaust of a simulated component to connect to one or more emission capturing components existing within the simulation environment.

18. The system of claim 14,
wherein the simulation environment is configured to automatically add one or more emission reducing components to the simulation environment that at least partially consume emissions produced by one or more components; and
wherein the simulation environment is configured to automatically modify an emissions exhaust of one or more simulated component to connect to an input for the one or more mission reducing components.

19. The system of claim 14,
wherein the simulation environment is configured to automatically replace one or more simulated components in the simulation environment with one or more process components that at least partially consume emissions produced by one or more components; and
wherein the simulation environment is configured to automatically modify an emissions exhaust of one or more simulated component to connect to an input for the one or more process components.

20. The system of claim 14,
wherein the one or more non-transitory computer readable media further include program instructions thereon that when executed cause the one or more computers to:
execute, by the one or more processors, a process configuration change in a real-world process that directs the emissions to one or more emission consuming components that currently exist in the real-world process.
